(19) United States
(12) Patent Application Publication
(10) Pub. No.: US 2023/0122332 A1
(43) Pub. Date: Apr. 20, 2023

(54) EPITAXIAL FILM WITH MULTIPLE STRESS STATES AND METHOD THEREOF

(71) Applicant: National Cheng Kung University, Tainan City (TW)

(72) Inventors: Jan-Chi Yang, Tainan City (TW); Chia-Chun Wei, Tainan City (TW)

(73) Assignee: National Cheng Kung University, Tainan City (TW)

(21) Appl. No.: 18/082,904

(22) Filed: Dec. 16, 2022

Related U.S. Application Data
(63) Continuation-in-part of application No. 17/207,961, filed on Mar. 22, 2021.

(30) Foreign Application Priority Data
Oct. 22, 2020 (TW) 109136658
Oct. 24, 2022 (TW) 111140294

(51) Int. Cl. C30B 23/04; C30B 29/32; C30B 29/24; C30B 29/20; C30B 29/06; C30B 23/02; C30B 33/10; C30B 29/68

(52) U.S. Cl. CPC C30B 23/04; C30B 29/32; C30B 29/24; C30B 29/20; C30B 29/06; C30B 23/025; C30B 33/10; C30B 29/68

(57) ABSTRACT

A method for manufacturing epitaxial films with multiple stress states, comprising steps of: providing a first single crystal substrate, and forming a sacrificial layer and a first epitaxial film on the first single crystal substrate, wherein the first epitaxial film is made of a first material;

removing the sacrificial layer to separate the first epitaxial film from the first single crystal substrate; transferring the first epitaxial film to a second single crystal substrate, wherein the second single crystal substrate is made of a second material, a partial surface of the second single crystal substrate being overlapped by the first epitaxial film; applying epitaxies onto the first epitaxial film and the second single crystal substrate to form a second epitaxial film on the first epitaxial film and the second single crystal substrate.

### TECHNICAL FIELD

The present disclosure is in related to an epitaxial film and a manufacturing method thereof, more particularly to an epitaxial film with multiple stress states and a method thereof.

### BACKGROUND

Epitaxy is a manufacturing method to produce semiconductor elements. That is, a new crystal is grown up on an original wafer to form a new semiconductor layer, so it is also called epitaxial growth. The epitaxial technology is applied to produce various components such as silicon transistors to CMOS integrated circuits, and epitaxy is especially important when manufacturing compound semiconductors such as gallium arsenide epitaxial wafers.

In the field of epitaxy, there is another type called Heteroepitaxy, which points out different aspect. That is, using different materials to grow up crystal on a substrate, in order to generate a crystal layer with various materials.

In Heteroepitaxy, when the difference in lattice constant between the substrate and the grown film approaches to a certain level, the film will generate a condition of volumetric strain. In the meantime, an additional energy may be activated, so as to build up a bandgap system, which is very potential to the field of semiconductor.

Thus, how to proceed aforesaid Heteroepitaxy becomes an issue to people having ordinary skill in the art.

### SUMMARY

The objective of the present disclosure provides an epitaxial film and a manufacturing method thereof. Through plural substrates with different materials and epitaxial materials to deposit epitaxies is to form plural zones with various stress states on a same epitaxial film. The technical part is as following.

A method for manufacturing epitaxial films with multiple stress states, comprising steps of: providing a first single crystal substrate, and forming a sacrificial layer and a first epitaxial film, wherein the first epitaxial film is made of a first material; removing the sacrificial layer, in order to separate the first epitaxial film from the first single crystal substrate; transferring the first epitaxial film to a second single crystal substrate, wherein the second single crystal substrate is made of a second material, a partial surface of the second single crystal substrate being overlapped by the first epitaxial film; applying epitaxies onto the first epitaxial film and the second single crystal substrate, in order to form a second epitaxial film on the first epitaxial film and the second single crystal substrate, wherein the second epitaxial film is made of a third material; wherein the first material, the second material and the third material are different.

The accompanying drawings are incorporated in and constitute a part of this application and, together with the description, serve to explain the principles of the disclosure in general terms. Like numerals refer to like parts throughout the disclosure.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1 illustrates a schematic view of an embodiment of an epitaxial film 100 of the present disclosure;

FIG. 2 illustrates a flow chart of the method for manufacturing epitaxial films 100 with multiple stress states;

FIG. 3A to FIG. 3D illustrate schematic views of an embodiment of the method for manufacturing epitaxial films 100 with multiple stress states;

FIG. 4A and FIG. 4B illustrate schematic views of another embodiment of an epitaxial film 200;

FIG. 5A illustrates an epitaxial film image of the epitaxial film 100 of the present disclosure displayed by a transmission electron microscope;

FIG. 5B illustrates a diffraction view of a second single crystal substrate;

FIG. 5C illustrates a diffraction view of a first epitaxial zone;

FIG. 5D illustrates a diffraction view of a second epitaxial zone; and

FIG. 6 illustrates a relationship betweem a binding energy and an interlayer distance.

### DETAILED DESCRIPTION

In order to describe in detail the technical content, structural features, achieved objectives and effects of the instant application, the following detailed descriptions are given in conjunction with the drawings and specific embodiments. It should be understood that these embodiments are only used to illustrate the application and not to limit the scope of the instant application.

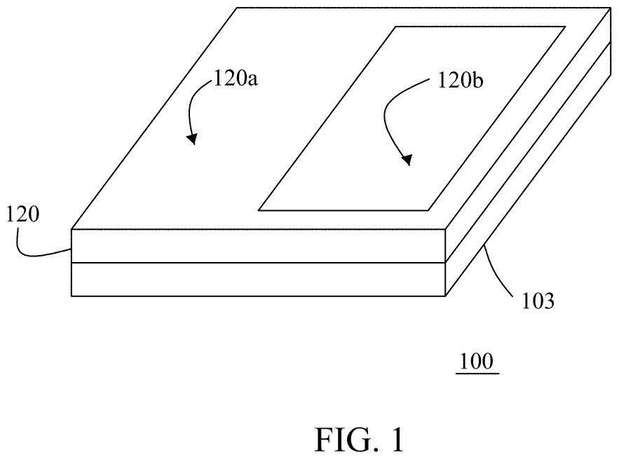

With reference to FIG. 1, which illustrates a schematic view of an embodiment of an epitaxial film 100 of the present disclosure. The epitaxial film 100 is with various stress states and made of epitaxies. According to FIG. 1, the epitaxial film 100 includes a second single crystal substrate 103 and a second epitaxial film 120, and the second epitaxial film 120 are formed on the second single crystal substrate 103 by epitaxies. The second epitaxial film 120 further includes a first epitaxial section 120a and a second epitaxial section 120b, which are with different stress states or strain states. Theoretically, strain is caused by stress, therefore each stress state corresponds to each strain state thereof. For the field of semiconductor, the stress state of a material is applied to control a junction potential and a bandgap system, that is why the epitaxial film 100 has different kinds of stress states. Obviously, it is beneficial to control a junction potential and a bandgap system. Following will describe a method for manufacturing epitaxial films with multiple stress states.

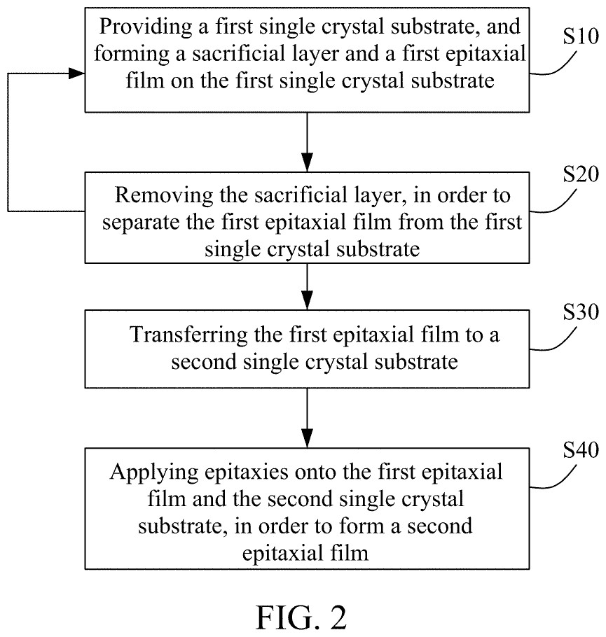

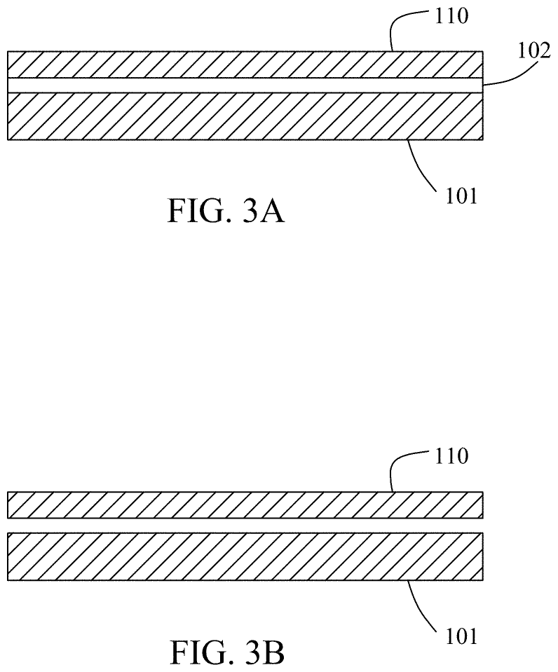

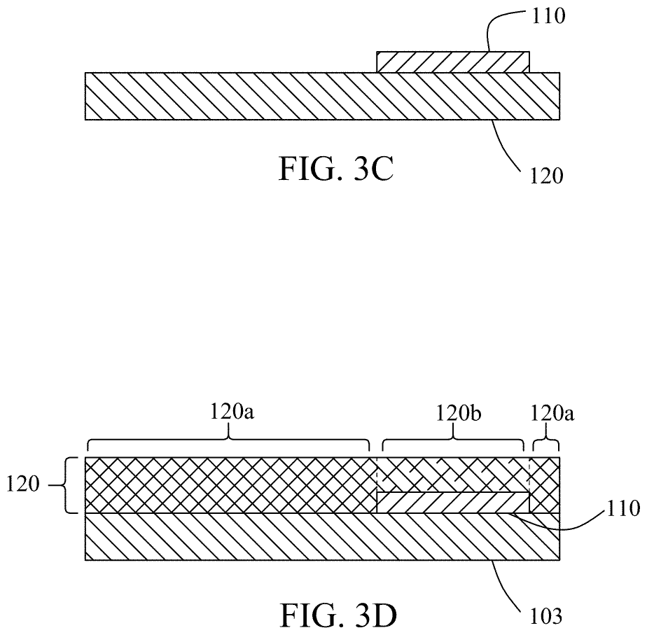

Please refer to FIG. 2 and FIG. 3A to FIG. 3D, which illustrate a flow chart of the method for manufacturing epitaxial films 100 with multiple stress states, and schematic views of an embodiment of the method for manufacturing epitaxial films 100 with multiple stress states. One thing to be noted, FIG. 3A to FIG. 3D are not shown in proportional rate. With reference to FIG. 3A, a step (S10) is to provide a first single crystal substrate 101, then a sacrificial layer 102 and a first epitaxial film 110 are formed on the first single crystal substrate 101, that is, forming the sacrificial layer 102 is first, the first epitaxial film 110 is thus formed on the sacrificial layer 102. The first single crystal substrate 101 is made of a first material, then through epitaxies, the first epitaxial film 110 is produced by the first material. The thickness of the first epitaxial film 110 is between 0.4 to 200 nm, and the sacrificial layer 102 is LSMO (Lanthanum Strontium Manganese Oxide), for example. For the embodiment, the first material is STO (Strontium Titanate). Definitely, people skilled in the art may have other options, such as materials and epitaxial technologies. As an example, the first material may be selected from the group consisting of: STO (Strontium Titanate), LAO (Lanthanum Aluminate), NGO (Neodymium Gallate; NdGaO₃), and monocrystalline silicon. The sacrificial layer 102 is chosen from the group consisting of: LSMO (Lanthanum Strontium Manganite), Sr₃Al₂O₆, YBCO (Yttrium barium copper oxide), and SrRuO₃ (Strontium Ruthenate).

Regarding to FIG. 3B, a step (S20) is of removing the sacrificial layer 102, in order to separate the first epitaxial film 110 from the first single crystal substrate 101. For this embodiment, the first single crystal substrate (101), the sacrificial layer 102 and the first epitaxial film 110 are immersed in an etching solution, so as to remove the sacrificial layer 102 because of etching. After the first epitaxial film 110 and the first single crystal substrate 101 being separated from each other, the first epitaxial film 110 is appeared.

In regarding to FIG. 3C, a step (S30) is of transferring the first epitaxial film 110 to a second single crystal substrate 103, and a partial surface of the second single crystal substrate 103 being overlapped by the first epitaxial film 110. The second single crystal substrate 103 is made of a second material such as LAO. Obviously, the first material and the second material must be different. In practice, the first material is LAO, the second material may be others except LAO. Further in detail, the first epitaxial film 110 and the second single crystal substrate 103 must be different materials, and with different lattice constants as well, that is for sure.

Based on the needs of requirements, the second material may be selected from the group consisting of STO, LAO, NGO, alumina, and monocrystalline silicon. For here, the first epitaxial film 110 is STO, and the second single crystal substrate 103 is LAO.

With reference to FIG. 3D, a step (S40) is of applying epitaxies onto the first epitaxial film 110 and the second single crystal substrate 103, in order to form a second epitaxial film 120 on the first epitaxial film 110 and the second single crystal substrate 103, wherein the second epitaxial film 120 is made of a third material, such as BFO, but other embodiments can be other materials except BFO. In the meantime, the second epitaxial film 120 individually forms a first epitaxial zone 120a and a second epitaxial zone 120b on the first epitaxial film 110 and the second single crystal substrate 103. Since the second epitaxial film 120 of the first epitaxial zone 120a and the second epitaxial film 120 of the second epitaxial zone 120b are formed on different materials with different lattice constants, that is, the first epitaxial film 110 (STO) and the second single crystal substrate 103 (LAO). Therefore, even the second epitaxial film 120 of the first epitaxial zone 120a and the second epitaxial film 120 of the second epitaxial zone 120b are the same material, different strain states may still happen. In other words, the stress state of the second epitaxial film 120 on the first epitaxial film 110 differs from the stress state of the second epitaxial film 120 on the second single crystal substrate 103.

In the step (S10) and the step (S40), the Pulsed Laser Deposition is adopted to deposit the first epitaxial film 110, the sacrificial layer 102 or the second epitaxial film 120, but other embodiments may use MOCVD (Metal-organic Chemical Vapor Deposition), MBE (Molecular Beam Epitaxy), LPE (Liquid Phase Epitaxy), VPE (Vapor Phase Epitaxy), SEG (Selective Epitaxial Growth), etc.

Therefore, through the step (S10) to the step (S40), the epitaxial film 100 with multiple stress states is produced, further to control a junction potential and a bandgap system by using the stress state difference among the epitaxial zones.

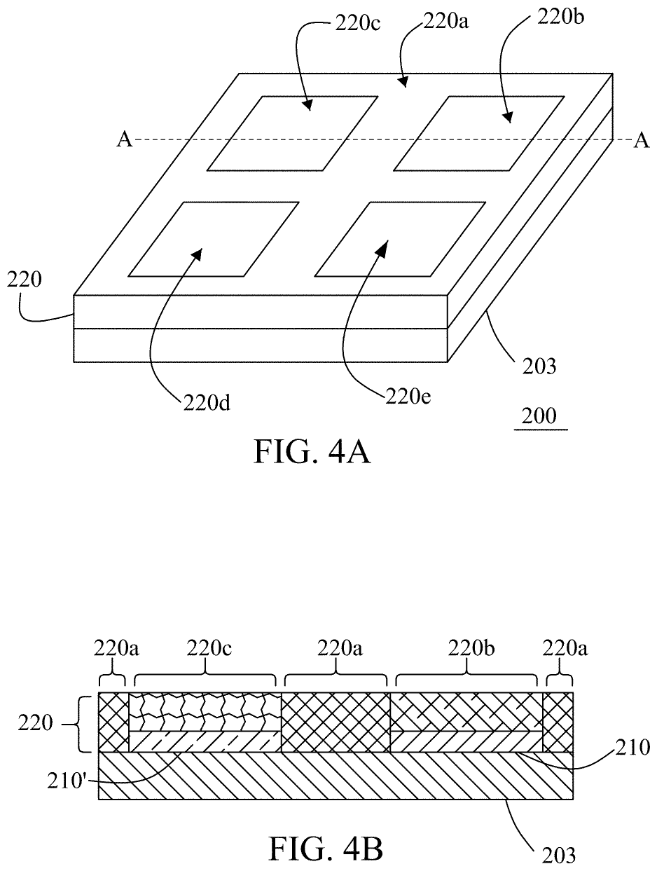

In relation to FIG. 2, FIG. 4A and FIG. 4B, wherein FIG. 4A and FIG. 4B illustrate schematic views of another embodiment of an epitaxial film 200. FIG. 4B is a cross-sectional view of the dotted line A-A in FIG. 4A. In the embodiment, a plurality of first epitaxial films 210 are gained through repeating the step (S10) and the step (S20). During the repeat, the first material may or may not be the same to form the first epitaxial film 210. For instance, the four first epitaxial film 210 are formed after repeating the step (S10) to the step (S20) four times, but the first material of the four first epitaxial film 210 can be STO, STO, LAO, and NGO, respectively.

The following step (S30) is of transferring the first epitaxial film 210 to different zones on a second single crystal substrate 203, and a partial surface of the second single crystal substrate 203 being overlapped by the first epitaxial film 210. Continuously, the step (S40) is of applying epitaxies onto the first epitaxial film 210 and the second single crystal substrate 203, in order to form a second epitaxial film 220. So that, the epitaxial film 200 shown in FIG. 4A and FIG. 4B is thus acquired.

As shown in FIG. 4A and FIG. 4B, the second epitaxial film 220 further has plural epitaxial zones 220a-220e, which are formed on different first epitaxial films 210. According to FIG. 4B, the epitaxial zone 220b is formed based on the first epitaxial film 210, and the epitaxial zone 220c is deposited on the first epitaxial film 210′. The materials of the first epitaxial film 210 and the first epitaxial film 210′ are not the same, even the epitaxial zone 220b and the epitaxial zone 220c belong to the second epitaxial film 220, and with various stress states. As a conclusion, the epitaxial film 220 with the epitaxial zones 220a-220e has multiple stress states. In other words, through the plurality of first epitaxial films 210 and the different materials, the epitaxial zones with more stress states are gained while forming the second epitaxial films 220.

Aforesaid embodiments disclose that the square and neatly arranged epitaxial zones 120b and 220b-220d are formed by the square second epitaxial films 110 and 210 distributed on the second single crystal substrates 103 and 203 in order, but not limited thereto. The shapes of the second epitaxial films can be others, and the arrangements for the second epitaxial films are others as well, such as irregular arrangements.

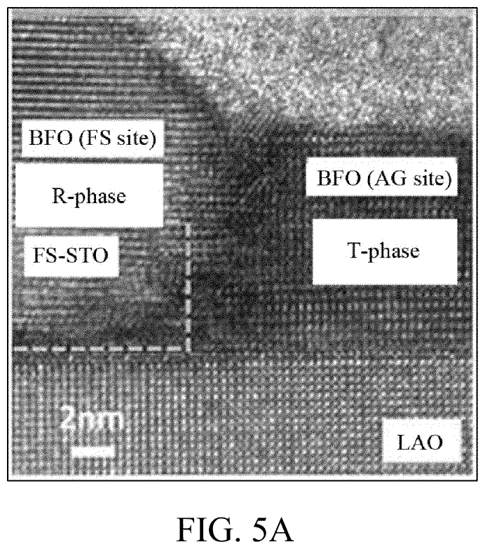

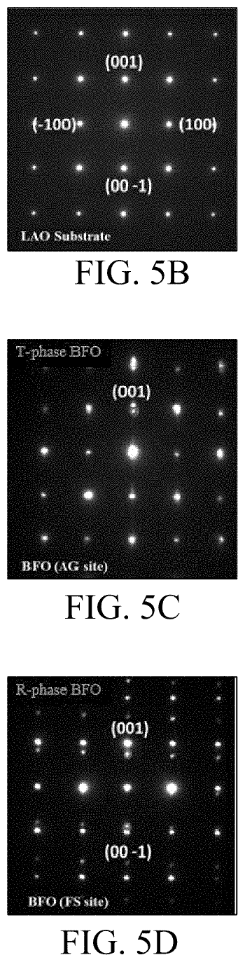

With regard to FIG. 5A, which illustrates an epitaxial film image of the epitaxial film 100 of the present disclosure displayed by a transmission electron microscope. LAO is the material for the second single crystal substrate, and STO and BFO are for the first epitaxial film and the second epitaxial film respectively. As shown in FIG. 5, the image of the second single crystal substrate (LAO), the first epitaxial film (FS-STO) and the second epitaxial film (BFO(AG site)) shows that every lattice arrangement is obviously distinct.

A first epitaxial zone located on the second single crystal substrate is called T-phase, which is deeply affected by the second single crystal substrate in lattice arrangement to generate similar lattice arrangement. The second epitaxial zone on the first epitaxial film is called R-phase, which is deeply affected by the first epitaxial film in lattice arrangement to generate similar lattice arrangement. As it can be understood, the lattice arrangements of the upper epitaxial film will be affected through the thinner epitaxial film. Due to the difference between the T-phase and the R-phase in lattice arrangements, zones with different lattice arrangements are formed on a same substrate (the second single crystal substrate) in order to provide different stress states. The characteristic can be fully applied to control a junction potential and a bandgap system. For example, through the first epitaxial films with different materials forming plural zones with different stress states on the same second single crystal substrate is to build up a bandgap system.

In accordance with FIG. 5B to FIG. 5D, FIG. 5B illustrates a diffraction view of the second single crystal substrate, FIG. 5C illustrates a diffraction view of the first epitaxial zone, and FIG. 5D illustrates a diffraction view of the second epitaxial zone. According to those figures, the diffraction views of the second epitaxial substrate, the T-phase and the R-phase are different, which means different stress states.

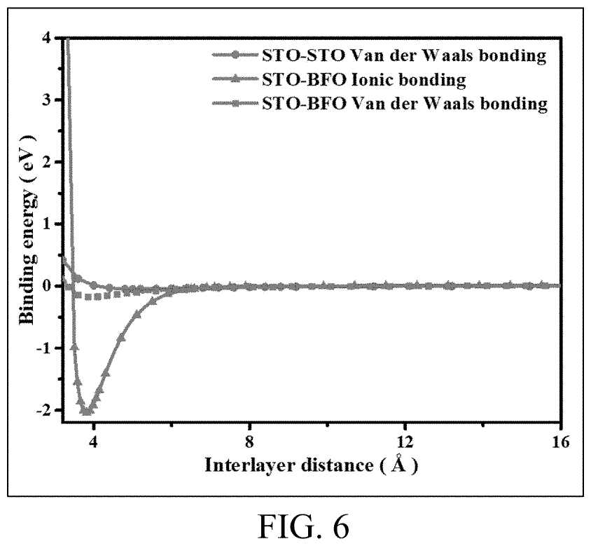

The embodiment in FIG. 5A discloses the thickness of the first epitaxial film is 5 to 7 nm. After calculations, even the thickness is less than 2 nm, the first epitaxial film is able to change the lattice arrangements of the upper epitaxial film. Please refer to FIG. 6, which illustrates a relationship between a binding energy and an interlayer distance. FIG. 6 respectively illustrates the Van der Waals bonding of homogenous bonding (STO-STO), ionic bonding and Van der Waals bonding of heterojunction (STO-BFO). As shown in figure, for the ionic bonding and Van der Waals bonding, the interlayer distance of heterojunction (STO-BFO) is about 4 Å (0.4 nm), and the bonding energy approaches the minimum value. Thus, more stable and strength for bonding is provided, and the corresponding lattice arrangements are generated while in the epitaxial process. Therefore, the first epitaxial film with thickness more than 0.4 nm is capable of changing the lattice arrangements of the upper epitaxial film.

Although the disclosure has been disclosed and illustrated with reference to particular embodiments, the principles involved are susceptible for use in numerous other embodiments that will be apparent to a person having ordinary skill in the art. This disclosure is, therefore, to be limited only as indicated by the scope of the appended claims.

What is claimed is:

1. A method for manufacturing epitaxial films with multiple stress states, comprising steps of:
(a) providing a first single crystal substrate, and forming a sacrificial layer and a first epitaxial film on the first single crystal substrate, wherein the first epitaxial film is made of a first material;
(b) removing the sacrificial layer, in order to separate the first epitaxial film from the first single crystal substrate;
(c) transferring the first epitaxial film to a second single crystal substrate, wherein the second single crystal substrate is made of a second material, a partial surface of the second single crystal substrate being overlapped by the first epitaxial film;
(d) applying epitaxies onto the first epitaxial film and the second single crystal substrate, in order to form a second epitaxial film on the first epitaxial film and the second single crystal substrate, wherein the second epitaxial film is made of a third material;
wherein the first material, the second material and the third material are different.

2. The method for manufacturing epitaxial films with multiple stress states according to claim 1, wherein the step (a) to the step (b) are repeated plural times in order to acquire the plurality of first epitaxial films, the first epitaxial film being transferred to different zones of the second single crystal substrate in the step (c).

3. The method for manufacturing epitaxial films with multiple stress states according to claim 2, wherein the first material and the second material are selected from the group consisting of: strontium titanate, lanthanum aluminate, neodymium gallate, alumina, and monocrystalline silicon.

4. The method for manufacturing epitaxial films with multiple stress states according to claim 2, wherein the third material is bismuth ferrite.

5. The method for manufacturing epitaxial films with multiple stress states according to claim 1, wherein the first single crystal substrate, the sacrificial layer and the first epitaxial film are immersed in an etching solution, so as to remove the sacrificial layer.

6. The method for manufacturing epitaxial films with multiple stress states according to claim 1, wherein the sacrificial layer is lanthanum strontium manganese oxide material.

7. The method for manufacturing epitaxial films with multiple stress states according to claim 1, wherein a thickness of the first epitaxial film is between 0.4 to 200 nm.

8. The method for manufacturing epitaxial films with multiple stress states according to claim 1, a pulsed laser deposition technology, a metal organic chemical vapor deposition, a molecular beam epitaxy, a liquid phase epitaxy, a vapor phase epitaxy, a sputtering or selective epitaxies are used to form the sacrificial layer and the first epitaxial film on the first single crystal substrate in the step (a).

9. The method for manufacturing epitaxial films with multiple stress states according to claim 1, a pulsed laser deposition technology, a metal organic chemical vapor deposition, a molecular beam epitaxy, a liquid phase epitaxy, a vapor phase epitaxy, a sputtering or selective epitaxies are used to form the second epitaxial film on the first epitaxial film and the second single crystal substrate in the step (d).

10. An epitaxial film with multiple stress states made by a method comprising steps of:
(a) providing a first single crystal substrate, and forming a sacrificial layer and a first epitaxial film on the first single crystal substrate, wherein the first epitaxial film is made of a first material;
(b) removing the sacrificial layer, in order to separate the first epitaxial film from the first single crystal substrate;
(c) transferring the first epitaxial film to a second single crystal substrate, wherein the second single crystal substrate is made of a second material, a partial surface of the second single crystal substrate being overlapped by the first epitaxial film;
(d) applying epitaxies onto the first epitaxial film and the second single crystal substrate, in order to form a second epitaxial film on the first epitaxial film and the second single crystal substrate, wherein the second epitaxial film is made of a third material;
wherein the first material, the second material and the third material are different.

11. The epitaxial film with multiple stress states according to claim 10, wherein the step (a) to the step (b) are repeated plural times in order to acquire the plurality of first epitaxial films, the first epitaxial film being transferred to different zones of the second single crystal substrate in the step (c).

12. The epitaxial film with multiple stress states according to claim 11, wherein the first material and the second material are selected from the group consisting of: strontium titanate, lanthanum aluminate, neodymium gallate, alumina, and monocrystalline silicon.

13. The epitaxial film with multiple stress states according to claim 11, wherein the third material is bismuth ferrite.

14. The epitaxial film with multiple stress states according to claim 10, wherein the first single crystal substrate, the sacrificial layer and the first epitaxial film are immersed in an etching solution, so as to remove the sacrificial layer.

15. The epitaxial film with multiple stress states according to claim 10, wherein the sacrificial layer is lanthanum strontium manganese oxide material.

16. The epitaxial film with multiple stress states according to claim 10, wherein a thickness of the first epitaxial film is between 0.4 to 200 nm.

17. The epitaxial film with multiple stress states according to claim 10, a pulsed laser deposition technology, a metal organic chemical vapor deposition, a molecular beam epitaxy, a liquid phase epitaxy, a vapor phase epitaxy, a sputtering or selective epitaxies are used to form the sacrificial layer and the first epitaxial film on the first single crystal substrate in the step (a).

18. The epitaxial film with multiple stress states according to claim 10, a pulsed laser deposition technology, a metal organic chemical vapor deposition, a molecular beam epitaxy, a liquid phase epitaxy, a vapor phase epitaxy, a sputtering or selective epitaxies are used to form the second epitaxial film on the first epitaxial film and the second single crystal substrate in the step (d).
